(19) United States
(12) Patent Application Publication
(10) Pub. No.: US 2012/0003764 A1
(43) Pub. Date: Jan. 5, 2012

(54) METHOD OF PRODUCING ORGANIC LIGHT-EMITTING DEVICE

(75) Inventors: Atsushi Koike, Kawasaki-shi (JP); Makoto Kameyama, Tokyo (JP)

(73) Assignee: CANON KABUSHIKI KAISHA, Tokyo (JP)

(21) Appl. No.: 13/257,087

(22) PCT Filed: Apr. 8, 2010
(86) PCT No.: PCT/JP2010/056729

§ 371 Date: Sep. 16, 2011

(30) Foreign Application Priority Data
May 12, 2009 (JP) 2009-115379

(51) Int. Cl. H01L 51/56

(52) U.S. Cl. 438/26; 257/E51.018

(57) ABSTRACT

Produced is an organic light-emitting device with high reliability without causing any degradation in light emission characteristics by preventing the intrusion of moisture with respect to an organic light-emitting element. Provided is a method of producing an organic light-emitting device including a substrate 101, an organic light-emitting element provided on the substrate 101, and a resin protective film 109 covering the organic light-emitting element, the method including: moving the substrate provided with the organic light-emitting element into a printing chamber; and screen printing using a screen printing plate to form the resin protective film, in which a non-printing region of the screen printing plate has a projection 212 or a non-printing region of the substrate has a projection 213, and the screen printing plate forms the resin protective film while being in contact with the substrate 101 via the projection.

### TECHNICAL FIELD

The present invention relates to a method of producing an organic light-emitting device.

### BACKGROUND ART

In recent years, an organic light-emitting device using an organic light-emitting element that is a self-emitting device is drawing attention as a flat panel display. However, it is known that the organic light-emitting element is extremely sensitive to moisture and oxygen, and a non-light-emitting region called a dark spot is formed, for example, due to the intrusion of moisture into the organic light-emitting element, with the result that light emission cannot be maintained.

As one method of preventing the intrusion of moisture into the organic light-emitting element, Japanese Patent Application Laid-Open No. 2003-282240 discloses a method of forming a protective film composed of a resin protective film and an inorganic protective film on an organic light-emitting element. Here, the resin protective film covers an organic light-emitting element and the surface of a substrate around the organic light-emitting element, and flattens the unevenness thereof. The inorganic protective film covers a flat resin film, an edge thereof, and the surface of a substrate around the resin film (surface having no film with moisture permeability enabling the intrusion of moisture to the organic light-emitting element in an underlying layer). According to such configuration, moisture proofness can be realized with a much smaller thickness compared with the case of preventing the intrusion of moisture to an organic light-emitting element having unevenness only with an inorganic protective film, whereby the degradation in the organic light-emitting element can be prevented.

Further, as a method of forming a resin protective film in such configuration, Japanese Patent Application Laid-Open No. 2006-147528 discloses a screen printing method in terms of the stability of a thickness, the flatness of a formed film, the patterning performance, and the like.

In the sealing configuration composed of the resin protective film and the inorganic protective film, most regions of the inorganic protective film are formed on the flat resin protective film. Therefore, a film that is homogeneous and has satisfactory moisture proofness without any defects can be formed by a vapor deposition method (chemical vapor deposition method, sputtering method, vacuum evaporation method, etc.) that is a general procedure. However, the inorganic protective film formed on the surface of the substrate around the resin protective film is not necessarily in the same situation.

More specifically, in the case where foreign matters and unevenness caused by surface defects and the like are generated in the region before the formation of the inorganic protective film, the inorganic protective film cannot cover them completely, or the density of a film to be formed in a side surface portion of the unevenness decreases, even if the inorganic protective film can cover them, with the result that satisfactory moisture proofness cannot be realized.

According to the formation of a resin protective layer by screen printing, a screen printing plate is placed on a substrate at a distance. Then, a rubber blade called a squeegee is moved under a pressure to bring the screen printing plate into contact with the substrate, whereby a resin is transferred to the surface of the substrate through an opening of the screen printing plate. In an outer peripheral portion of the opening of the screen printing plate, the resin comes around and the foreign matters formed of the cured resin are deposited. Then, there is a problem in that, when the deposits and the screen printing plate itself are rubbed against the surface of the substrate, surface defects (unevenness) such as the adhesion of the foreign matters and scars are generated on the surface of the substrate.

### SUMMARY OF THE INVENTION

An object of the present invention is to provide a production method capable of producing an organic light-emitting device with high reliability without causing the degradation in light emission characteristics by preventing the intrusion of moisture with respect to the organic light-emitting element.

To be specific, a method of producing an organic light-emitting device of the present invention has the following features. That is, an organic light-emitting device produced by the method of producing an organic light-emitting device of the present invention includes a substrate, an organic light-emitting element provided on the substrate, and a resin protective film covering the organic light-emitting element, and the method of producing an organic light-emitting device includes: moving a substrate provided with an organic light-emitting element into a printing chamber, in which a lower electrode, a light-emitting layer, and an upper electrode are provided in the mentioned order on the substrate in the organic light-emitting element; and screen printing using a screen printing plate to form a resin protective film, in which a non-printing region of the screen printing plate has a projection or a non-printing region of the substrate has a projection, and the screen printing plate forms the resin protective film while being in contact with the substrate via the projection.

Further features of the present invention will become apparent from the following description of exemplary embodiments with reference to the attached drawings.

### BRIEF DESCRIPTION OF THE DRAWINGS

FIG. 1 is a schematic cross-sectional view illustrating an organic light-emitting device produced in an embodiment of the present invention.

FIG. 2 is a schematic cross-sectional view illustrating an organic light-emitting device produced in Embodiment 1 of the present invention.

FIG. 3 is a schematic cross-sectional view illustrating an organic light-emitting device produced in Embodiment 1 of the present invention.

FIG. 4 is a schematic cross-sectional view illustrating an organic light-emitting device produced in Embodiment 2 of the present invention.

FIG. 5 is a schematic cross-sectional view illustrating an organic light-emitting device produced in a comparative example.

FIG. 6 is a perspective view illustrating a device used in a screen printing step in Example 1 of the present invention.

FIG. 7 is a perspective view illustrating a device used in a screen printing step in Example 2 of the present invention.

FIG. 8 is a perspective view illustrating a device used in a screen printing step in Example 3 of the present invention.

FIG. 9 is a schematic plan view illustrating a large substrate in an embodiment of the present invention.

### MODE FOR CARRYING OUT THE INVENTION

An organic light-emitting device produced by a production method of the present invention includes a substrate, an organic light-emitting element provided on the substrate, a resin protective film covering the organic light-emitting element, an inorganic protective film covering the resin protective film.

Further, a method of producing an organic light-emitting device of the present invention includes a screen printing step of forming a resin protective film by screen printing, and in the screen printing step, a resin protective film is formed around a printing region on the substrate in such a manner that the screen printing plate does not come into contact with the substrate.

Further, in such production method, the screen printing plate used in the screen printing step can have a protruding portion for preventing the contact between the substrate and the screen printing plate on a reverse surface that is an opposed surface of the substrate when the resin protective film is formed. Further, the substrate can have a protruding portion for preventing the contact between the substrate and the screen printing plate on the surface that is an opposed surface of the screen printing plate when the resin protective film is formed. Further, in the screen printing step, the substrate or a non-printing region of the screen printing plate can have a protruding portion for preventing the contact between the substrate and the screen printing plate.

Thus, according to the method of producing an organic light-emitting device of the present invention, when the resin protective film is formed, the screen printing plate does not come into contact with the surface of the substrate that is present around the resin protective film. Therefore, there are no surface defects (unevenness), such as the adhesion of foreign matters from the screen printing plate and scars caused when the foreign matters and the screen printing plate itself are rubbed against the substrate, and the inorganic protective film can cover the flat resin protective film, the edge thereof, and the surface of the substrate around the resin protective film satisfactorily. Thus, moisture infiltrated through a potion where the inorganic protective film is formed imperfectly and a portion where a film quality is degraded does not reach a display portion through the resin protective film in any way. Therefore, an organic light-emitting element can be obtained in which light emission characteristics caused by the intrusion of moisture are not degraded. Therefore, an organic light-emitting device with high reliability can be produced.

### Embodiment 1

Hereinafter, Embodiment 1 of the organic light-emitting device according to the present invention is described with reference to the drawings.

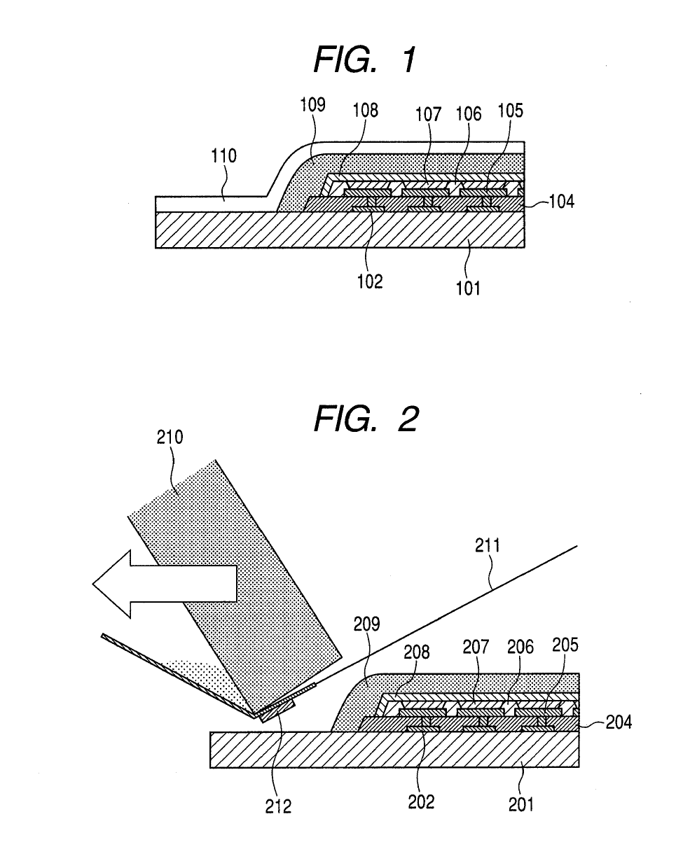

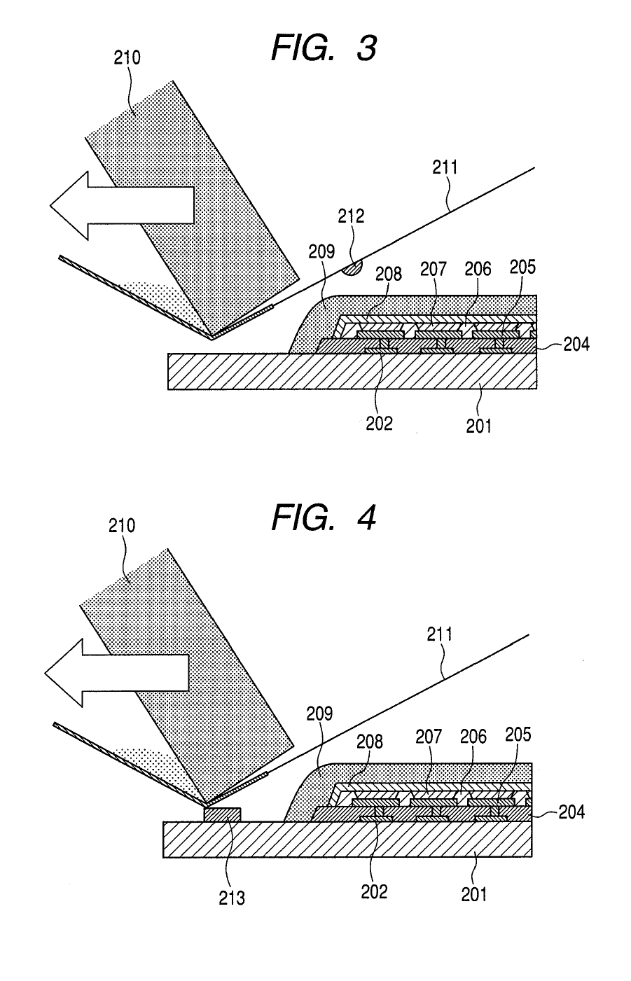

FIG. 1 is a schematic cross-sectional view illustrating an organic light-emitting device produced by the method of producing an organic light-emitting device according to the present invention. Further, FIGS. 2 and 3 are schematic cross-sectional views illustrating an organic light-emitting device produced in Embodiment 1 of the present invention. Here, in FIG. 1, the organic light-emitting device includes a substrate 101, a TFT circuit 102, a planarizing layer 104, a lower electrode 105, a bank 106, an organic compound layer 107, an upper electrode 108, a resin protective layer 109, and an inorganic protective film 110. Further, in FIGS. 2 and 3, the organic light-emitting device includes a substrate 201, a TFT circuit 202, a planarizing layer 204, a lower electrode 205, a bank 206, an organic compound layer 207, an upper electrode 208, a resin protective film 209, a blade 210, a screen printing plate 211, and a protruding portion 212.

First, an organic light-emitting element that is a constituent member of the organic light-emitting device is described.

As illustrated in FIG. 1, in the organic light-emitting device produced in Embodiment 1, the TFT circuit 102 is formed on the substrate 101. Here, examples of the substrate 101 used in the organic light-emitting device include a glass substrate, an insulating substrate made of a synthetic resin or the like, and a conductive substrate or semiconductor substrate on the surface of which an insulating layer made of silicon oxide, silicon nitride, or the like is formed. Further, the substrate 101 may be transparent or opaque.

On the substrate 101 including the TFT circuit 102, the planarizing layer 104 made of an acrylic resin, a polyimide-based resin, a norbornene-based resin, a fluorine-based resin, or the like is formed in a desired pattern by photolithography, for example. Here, the planarizing layer 104 is a layer for planarizing the unevenness generated by providing the TFT circuit 102. It should be noted that the material and production method for the planarizing layer 104 are not particularly limited as long as the planarizing layer 104 can flatten the unevenness generated by providing the TFT circuit 102. Further, an insulating layer (not shown) made of an inorganic material such as silicon nitride, silicon oxynitride, silicon oxide, or the like may be formed between the planarizing layer 104 and the TFT circuit 102.

The lower electrode (first electrode) 105 to be connected electrically to a part of the TFT circuit 102 provided on the planarizing layer 104 may be a transparent electrode or a reflective electrode. In the case where the lower electrode 105 is a transparent electrode, examples of the constituent material thereof include ITO and In₂O₃. In the case where the lower electrode 105 is a reflective electrode, examples of the constituent material thereof include: metal elements such as Au, Ag, Al, Pt, Cr, Pd, Se, and Ir; alloys formed of a combination of a plurality of those metal elements; and metal compounds such as copper iodide. The thickness of the lower electrode 105 is preferably 0.1 μm to 1 μm.

The bank (separation film) 106 is provided in a peripheral edge portion of the lower electrode 105. Examples of the constituent material for the bank 106 include an inorganic insulating layer made of silicon nitride, silicon oxynitride, silicon oxide, or the like, and an acrylic resin, a polyimide-based resin, and a novolac-based resin. The thickness of the bank 106 is preferably 1 μm to 5 μm.

The organic compound layer 107 provided on the lower electrode 105 may be formed of one layer or a plurality of layers, which can be selected appropriately considering the light emission function of the organic light-emitting element. Further, specific examples of the layer constituting the organic compound layer 107 include a hole injection layer, a hole transporting layer, a light-emitting layer, an electron transporting layer, and an electron injection layer. As the constituent materials for those layers, known compounds can be used. It should be noted that a light-emitting region in the organic compound layer 107 may be present in a particular layer or at an interface between adjacent layers. The organic compound layer 107 is formed by vacuum evaporation, an ink jet method, or the like. An organic compound layer is formed in a light-emitting area using a high-precision mask in the case of the evaporation or using high-precision ejection in the case of the inkjet method.

On the organic compound layer 107, the upper electrode (second electrode) 108 is formed. The upper electrode 108 may be a transparent electrode or a reflective electrode. As the constituent material for the upper electrode 108, the same material as that for the lower electrode 105 can be used.

By forming the upper electrode 108, an organic light-emitting element is formed on the substrate 101. Here, when an organic light-emitting element is formed on a large substrate, as illustrated in FIG. 9, a plurality of organic light-emitting elements 602 are arranged in a matrix on the large substrate 601.

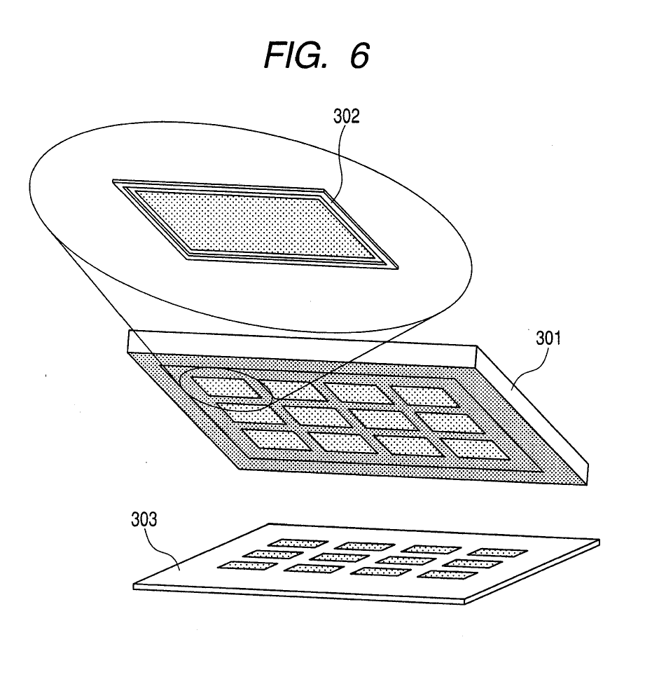

Next, the step of forming the resin protective film is described. In the present embodiment, first, a substrate having an organic light-emitting element formed thereon is moved into a printing chamber in a low dew point atmosphere. Next, as illustrated in FIG. 2, performed is the step of screen printing in which an adhesive to be the resin protective film 209 is printed on the organic light-emitting element by screen printing using a screen printer. It should be noted that FIG. 2 illustrates only the screen printing plate 211 and the blade 210. Further, a thin-line portion of the screen printing plate 211 represents a printing region, which corresponds to a so-called mesh portion. On the other hand, a thick-line portion of the screen printing plate 211 represents a non-printing region, which corresponds to a frame supporting the mesh portion. The screen printing plate used at this time is provided with a protruding portion 302 with a height of several μm to tens of μm in an outer periphery of a printing opening (region of about 0.5 mm to 1 mm from an opening end) of the opposed surface of the substrate 303, as illustrated in FIG. 6. Thus, the screen printing plate 301 does not come into contact with the surface of the substrate 303 positioned around the resin protective film.

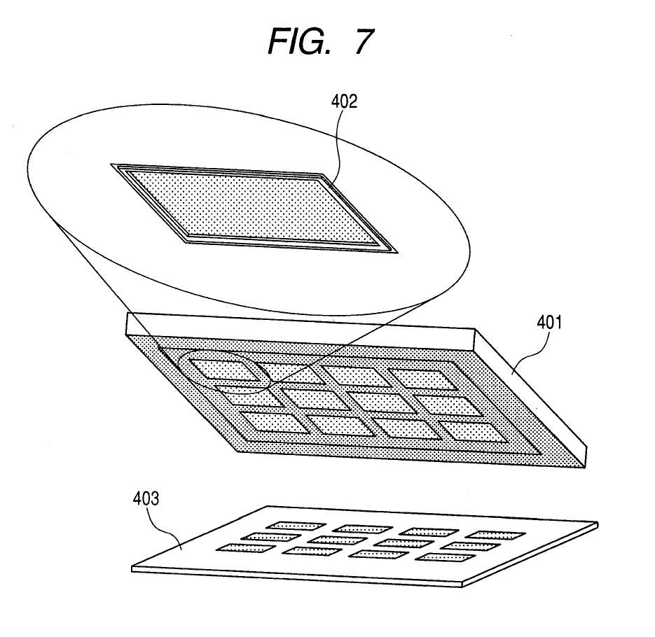

Alternatively, as illustrated in FIG. 3, performed is the step of screen printing in which an adhesive to be the resin protective film 209 is printed on the organic light-emitting element by screen printing using a screen printer. The screen printing plate 401 used at this time is provided with a protruding portion 402 with a height of tens of μm to twenties of μm in an inner periphery of a printing opening (region of about 0.3 mm to 0.8 mm from an opening end) of the opposed surface of the substrate 403, as illustrated in FIG. 7. Thus, the screen printing plate 401 does not come into contact with the surface of the substrate 403 positioned around the resin protective film 209. In this case, because the protruding portion 402 is formed in the printing region, the adhesive is not printed to this portion immediately after the printing. An adhesive with a viscosity to such a degree as used generally in screen printing fills this portion through flowability thereof, and hence, a non-printing region is not formed. Accordingly, a clean region without any defects with which the screen printing plate 211 does not come into contact is present in a width of about 0.5 mm from an end of the resin protective film 209, whereby the surface of the substrate 201 and the inorganic protective film can express sufficient moisture proofness.

As the adhesive to be the resin protective film 209 used for printing, specifically, a UV-curable adhesive, a thermosetting adhesive, or the like can be used as long as it does not contain a component that adversely affects the organic light-emitting element.

### Embodiment 2

Next, Embodiment 2 is described. The description of the elements similar to those in Embodiment 1 may be omitted. FIG. 4 is a schematic cross-sectional view illustrating an organic light-emitting device produced in Embodiment 2 of the present invention. Here, in FIG. 4, the organic light-emitting device includes a substrate 201, a TFT circuit 202, a planarizing layer 204, a lower electrode 205, a bank 206, an organic compound layer 207, an upper electrode 208, a resin protective film 209, a blade 210, a screen printing plate 211, and a protruding portion 213.

In the present embodiment, an organic light-emitting element to be formed on the substrate is formed by the same method as that in Embodiment 1.

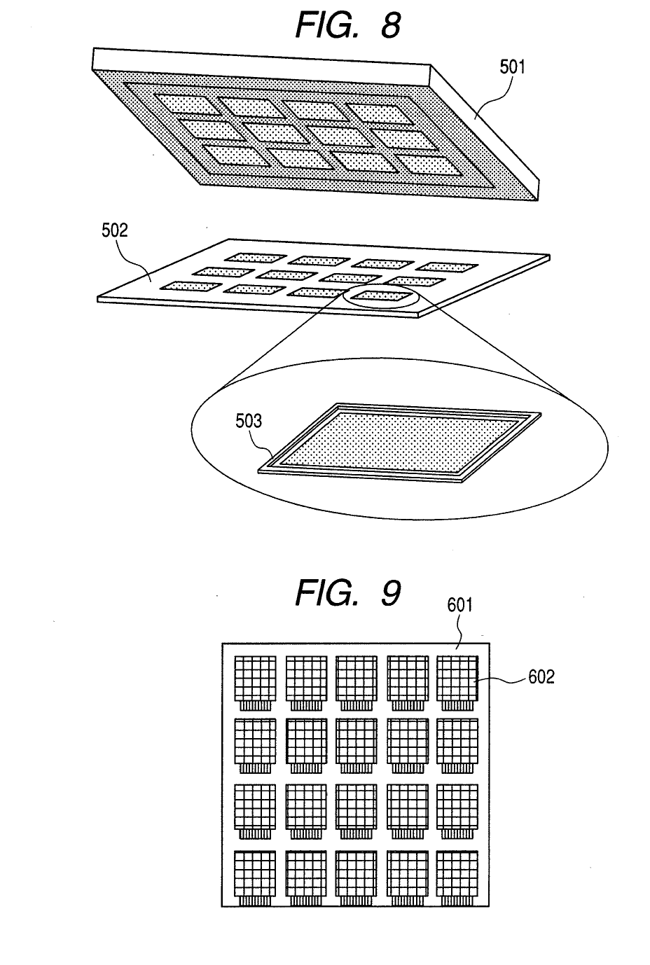

The step of forming a resin protective film is described. In the present embodiment, performed is the step of screen printing in which an adhesive to be the resin protective film 209 is printed on an organic light-emitting element on a substrate with the organic light-emitting element moved to a printing chamber in a low dew point nitrogen atmosphere by screen printing using a screen printer as illustrated in FIG. 4. In the step of screen printing, as illustrated in FIG. 8, the outer periphery of a resin protective film formation region on the surface of the substrate 502 (region of about 0.5 mm to 1 mm from an end of the resin protective film) is provided with a protruding portion 503 with a height of several μm to tens of μm. Thus, a screen printing plate 501 does not come into contact with the surface of the substrate 502 around the resin protective film. Accordingly, a clean region without any defects with which the screen printing plate 501 does not come into contact is present in a width of about 0.5 mm from an end of the resin protective film 209, whereby the surface of the substrate 502 and the inorganic protective film 110 can express sufficient moisture proofness.

### EXAMPLES

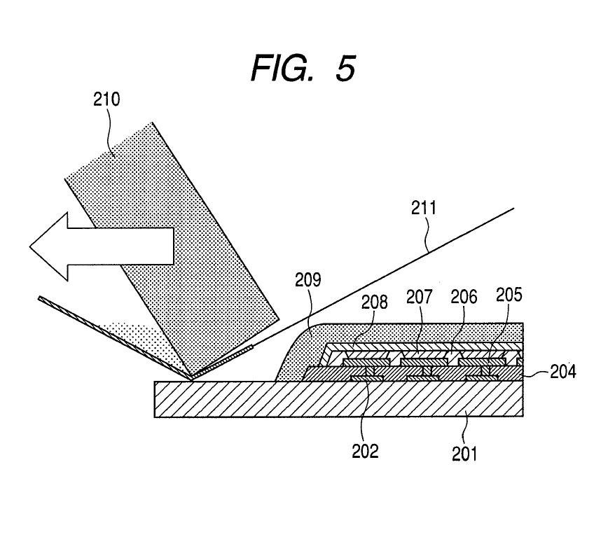

Next, specific examples of the present invention are described in detail. FIG. 5 is a schematic cross-sectional view illustrating an organic light-emitting device produced in a comparative example. Further, FIG. 6 is a perspective view illustrating a device used in a screen printing step in Example 1. FIG. 7 is a perspective view illustrating a device used in a screen printing step in Example 2. FIG. 8 is a perspective view illustrating a device used in a screen printing step in Example 3 of the present invention.

### Example 1

In Example 1, first, a TFT substrate having a lower electrode formed of Cr was subjected to UV/ozone cleaning. Then, in a photolithography step, a bank was patterned around the lower electrode. At this time, the thickness of the bank was 2 μm. Next, a hole transporting layer, a light-emitting layer, an electron transporting layer, and an electron injection layer constituting an organic compound layer were formed in the mentioned order by a vacuum evaporation method.

Specifically, first, an αNPD was formed on the lower electrode to form a hole transporting layer. At this time, the thickness of the hole transporting layer was 50 nm. Next, on the hole transporting layer, an aluminum chelate complex (Alq3) as a host and coumarin 6 as a guest were co-deposited so that the weight ratio was 100:6 to form a light-emitting layer. At this time, the thickness of the light-emitting layer was set at 50 nm. Next, a phenanthroline compound (Bphen) was formed into a film to form an electron transporting layer on the light-emitting layer. At this time, the thickness of the electron transporting layer was set at 10 nm. Next, a phenanthroline compound (Bphen) and cesium carbonate (Cs₂Co₃) were co-deposited so that the weight ratio was 100:1 to form an electron injection layer on the electron transporting layer. At this time, the thickness of the electron injection layer was set at 40 nm. Next, ITO was formed into a film by a sputtering method to form an upper electrode on the electron injection layer. At this time, the thickness of the upper electrode was set at 130 nm. The organic light-emitting element was produced by the above steps.

Next, a resin protective film was formed in a printing chamber in a low dew point nitrogen atmosphere. More specifically, as the step of screen printing, a thermosetting epoxy resin was printed on the substrate 201 provided with the organic light-emitting element by a screen printing method using a screen printer as illustrated in FIG. 2. A screen printing plate used herein is provided, as illustrated in FIG. 6, with a protruding portion 302 with a height of 10 μm in an outer periphery of a printing opening (region of 0.8 mm from an opening end) of an opposed surface of the substrate 303. Thus, the screen printing plate 301 does not come into contact with the surface of the substrate 303 positioned around the resin protective film to be formed.

After that, the resin protective film was cured by over-heating at 100° C. for 15 minutes in a vacuum environment. Here, the thickness of the resin protective film after the curing was set at 30 μm.

Next, an inorganic protective film made of silicon nitride was formed by a plasma CVD method using an SiH₄ gas, an N₂ gas, and an H₂ gas. Here, the thickness of the inorganic protective film was set at 1 μm. Further, the inorganic protective film covered the entire resin protective film and was formed in a width of about 1 mm on the substrate surface in an outer periphery of the resin protective film.

The organic light-emitting device formed as described above was subjected to a storage test in an environment of a temperature of 60° C. and a humidity of 90%. Consequently, a dark spot was not generated even in the result of the storage test of 1000 hours.

### Example 2

In Example 2, an organic light-emitting device was produced by the following method. It should be noted that the method of producing the organic light-emitting device is the same as that of Example 1, and hence, the detailed description thereof is omitted.

Next, a resin protective film was formed in a printing chamber in a low dew point nitrogen atmosphere on a substrate on which an organic light-emitting device had been formed. More specifically, as the step of screen printing, a thermosetting epoxy resin was printed on the substrate 201 provided with the organic light-emitting element by a screen printing method using a screen printer as illustrated in FIG. 3. A screen printing plate used was provided, as illustrated in FIG. 7, with a protruding portion 402 with a height of 20 μm in an inner periphery of a printing opening (region of 0.3 mm from an opening end) of an opposed surface of the substrate 403. Thus, the screen printing plate 401 was prevented from coming into contact with the surface of the substrate 403 positioned around the resin protective film.

After that, the resin protective film was cured by over-heating at 100° C. for 15 minutes in a vacuum environment. Here, the thickness of the resin protective film after the curing was set at 30 μm.

Next, an inorganic protective film made of silicon nitride was formed by a plasma CVD method using an SiH₄ gas, an N₂ gas, and an H₂ gas. Here, the thickness of the inorganic protective film was set at 1 μm. Further, the inorganic protective film covered the entire resin protective film and was formed in a width of about 1 mm on the substrate surface in an outer periphery of the resin protective film.

The organic light-emitting device formed as described above was subjected to a storage test in an environment of a temperature of 60° C. and a humidity of 90%. Consequently, a dark spot was not generated even in the result of the storage test of 1000 hours.

### Example 3

In Example 3, an organic light-emitting device was produced by the following method. It should be noted that the method of producing the organic light-emitting device is the same as that of Example 1, and hence, the detailed description thereof is omitted.

Next, a resin protective film was formed in a printing chamber in a low dew point nitrogen atmosphere on a substrate on which an organic light-emitting device had been formed. More specifically, as the step of screen printing, a thermosetting epoxy resin was printed on the substrate 201 provided with the organic light-emitting element by screen printing using a screen printer as illustrated in FIG. 4. At this time, the outer periphery of a resin protective film formation region on the surface of the substrate 502 (region of about 0.5 mm from an end of the resin protective film) was provided with a protruding portion 503 with a height of 2 μm when a bank was patterned. Thus, the screen printing plate 501 was prevented from coming into contact with the surface of the substrate 502 positioned around the resin protective film.

After that, the resin protective film was cured by over-heating at 100° C. for 15 minutes in a vacuum environment. Here, the thickness of the resin protective film after curing was set at 30 μm.

Next, an inorganic protective film made of silicon nitride was formed by a plasma CVD method using an SiH₄ gas, an N₂ gas, and an H₂ gas. Here, the thickness of the inorganic protective film was set at 1 μm. Further, the inorganic protective film covered the entire resin protective film and was formed in a width of about 1 mm on the substrate surface in an outer periphery of the resin protective film.

The organic light-emitting device formed as described above was subjected to a storage test in an environment of a temperature of 60° C. and a humidity of 90%. Consequently, a dark spot was not generated even in the result of the storage test of 1000 hours.

### Comparative Example

As a comparison, as illustrated in FIG. 5, printing was performed on the substrate 201 by a screen printing method using a screen printer. At this time, an organic light-emitting element was formed using a substrate 201 without a protruding portion for preventing the contact between the screen printing plate 211 and the substrate 201 for each of the screen printing plate 211 side and the substrate 201 side.

Then, a resin protective film was formed on the substrate with the organic light-emitting element formed thereon in a printing chamber in a low dew point nitrogen atmosphere. After that, the resin protective film was cured by over-heating at 100° C. for 15 minutes in a vacuum environment. Here, the thickness of the resin protective film after curing was set at 30 μm.

Next, an inorganic protective film made of silicon nitride was formed by a plasma CVD method using an SiH₄ gas, an N₂ gas, and an H₂ gas. Here, the thickness of the inorganic protective film was set at 1 μm. Further, the inorganic protective film covered the entire resin protective film and was formed in a width of about 1 mm on the substrate surface in an outer periphery of the resin protective film.

The organic light-emitting device formed as described above was subjected to a storage test in an environment of a temperature of 60° C. and a humidity of 90% for 1000 hours. Consequently, a dark spot was generated in a region with an average radius of 5 mm with respect to each of two points on the outer periphery of a display portion.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-115379, filed May 12, 2009, which is hereby incorporated by reference herein in its entirety.

1. A method of producing an organic light-emitting device comprising a substrate, an organic light-emitting element provided on the substrate, and a resin protective film covering the organic light-emitting element, the method comprising:
moving a substrate provided with an organic light-emitting element into a printing chamber, wherein a lower electrode, a light-emitting layer, and an upper electrode are provided in the mentioned order on the substrate in the organic light-emitting element; and
screen printing using a screen printing plate to form a resin protective film, wherein a non-printing region of the screen printing plate has a projection or a non-printing region of the substrate has a projection, and the screen printing plate forms the resin protective film while being in contact with the substrate via the projection.

2. The method of producing an organic light-emitting device according to claim 1, further comprising forming an inorganic protective film on the resin protective film.
